(19) United States
(12) Patent Application Publication
(10) Pub. No.: US 2022/0243013 A1
(43) Pub. Date: Aug. 4, 2022

(54) RESIN COMPOSITION, PREPREG OBTAINED USING SAME, RESIN-COATED FILM, RESIN-COATED METAL FOIL, METAL-CLAD LAMINATE, AND WIRING BOARD

(71) Applicant: PANASONIC INTELLECTUAL PROPERTY MANAGEMENT CO., LTD., Osaka (JP)

(72) Inventors: Hiroaki UMEHARA, Fukushima (JP); Yiqun WANG, Osaka (JP); Hiroharu INOUE, Osaka (JP)

(73) Assignee: PANASONIC INTELLECTUAL PROPERTY MANAGEMENT CO., LTD., Osaka (JP)

(21) Appl. No.: 17/438,207

(22) PCT Filed: Mar. 18, 2020
(86) PCT No.: PCT/JP2020/012109

§ 371 Date: Sep. 10, 2021

(30) Foreign Application Priority Data
Mar. 29, 2019 (JP) 2019-067682

(51) Int. Cl. C08G 65/40; C08L 25/04; C08J 5/24; C08L 35/00; H05K 1/03

(52) U.S. Cl. CPC C08G 65/4068; C08L 25/04; C08J 5/249; H05K 2201/0355; H05K 1/036; C08J 2371/12; C08L 35/00

(57) ABSTRACT

A resin composition includes a modified poly(phenylene ether) compound having a carbon-carbon unsaturated double bond at a molecular end, a maleimide compound having two or more N-substituted maleimide groups in the molecule, and a styrene-based polymer having a weight-average molecular weight less than 10,000.

### TECHNICAL FIELD

The present invention relates to a resin composition, and a prepreg, a film with resin, a metal foil with resin, a metal-clad laminate and a wiring board using the resin composition.

### BACKGROUND ART

Recently, in various electronic devices, increase in information throughput has led to rapid development in mounting technology such as heightening of integration, densifying of wiring, and multi-layering of a semiconductor device to be mounted. A substrate material for forming a base material of a printed wiring board used in various electronic devices is requested to have low dielectric constant and dielectric loss tangent so as to enhance the transmission rate of signals, and reduce the loss during signal transmission.

Recently, it has been found that maleimide compounds are excellent in dielectric characteristics such as low dielectric constant and low dielectric loss tangent (hereinafter, also referred to as low dielectric characteristics). For example, Patent Literature 1 reports that a resin composition having excellent curability in the presence of oxygen or under low temperature in addition to the characteristics such as low dielectric constant and low dielectric loss tangent is obtained by a curable resin composition containing a vinyl compound, a maleimide compound and a styrene-based thermoplastic elastomer. Although it is assumed that the dielectric characteristics can be improved by adding a styrene-based thermoplastic elastomer having a relatively large molecular weight as compared with the case where such an elastomer is not added, it is easy to imagine that this impairs the moldability.

When the resin composition is used as a molding material of a substrate material or the like, not only the excellent low dielectric characteristics and low expansion characteristics but also high glass transition temperature (Tg), and heat resistance and adhesiveness in a cured product of the resin composition are required. It is also requested to control moisture absorption to a base material of a wiring board by lowering water absorption of the cured product of the molding material so as to make the wiring board usable in a highly humid environment or the like. Further, progress in densification and multiplication of wiring leads to a demand for excellent moldability on substrate materials.

This being the case, in the current state, a substrate material for forming a base material of a wiring board is requested to provide a cured product having low water absorption, excellent heat resistance and adhesiveness, and low dielectric characteristics, and a prepreg, a film with resin, a metal foil with resin and the like containing the resin composition or a semi-cured product thereof are requested to have excellent moldability.

The present invention has been devised in light of the above circumstance, and an object thereof is to provide a resin composition combining excellent moldability in a prepreg, a film with resin, a metal foil with resin or the like containing the resin composition or a semi-cured product thereof, and low dielectric characteristics, high Tg and low coefficient of thermal expansion (CTE), adhesiveness, and low water absorption in a cured product of the resin composition. It is also an object of the present invention to provide a prepreg, a film with resin, a metal foil with resin, a metal-clad laminate, and a wiring board using the resin composition.

### CITATION LIST

### Patent Literature

Patent Literature 1: JP-B25649773

### SUMMARY OF INVENTION

A resin composition according to one aspect of the present invention includes a modified polyphenylene ether compound having a carbon-carbon unsaturated double bond at a molecular end, a maleimide compound having two or more N-substituted maleimide groups in one molecule, and a styrene-based polymer having a weight average molecular weight of less than 10000.

### BRIEF DESCRIPTION OF DRAWINGS

FIG. 1 is a schematic section view showing a configuration of a prepreg according to one embodiment of the present invention.

FIG. 2 is a schematic section view showing a configuration of a metal-clad laminate according to one embodiment of the present invention.

FIG. 3 is a schematic section view showing a configuration of a wiring board according to one embodiment of the present invention.

FIG. 4 is a schematic section view showing a configuration of a metal foil with resin according to one embodiment of the present invention.

FIG. 5 is a schematic section view showing a configuration of a resin film according to one embodiment of the present invention.

### DESCRIPTION OF EMBODIMENTS

A resin composition according to an embodiment of the present invention includes a modified polyphenylene ether compound having a carbon-carbon unsaturated double bond at a molecular end, a maleimide compound having two or more N-substituted maleimide groups in one molecule, and a styrene-based polymer having a weight average molecular weight of less than 10000.

According to such a configuration, it is possible to provide a resin composition combining excellent moldability in a prepreg, a film with resin, a metal foil with resin or the like containing the resin composition or a semi-cured product thereof, and low dielectric characteristics, high glass transition temperature (Tg) and high heat resistance, low coefficient of thermal expansion, adhesiveness, and low water absorption in a cured product of the resin composition. Further, according to the present invention, by using the resin composition, it is possible to provide a prepreg, a film with resin, a metal foil with resin, a metal-clad laminate, and a wiring board having excellent properties as described above.

Hereinafter, components of the resin composition according to the present embodiment are specifically described.

### Modified Polyphenylene Ether Compound

A modified polyphenylene ether compound used in the present embodiment is not particularly limited as long as it is a modified polyphenylene ether compound that is terminally modified with a substituent having a carbon-carbon unsaturated double bond. Containing such a modified polyphenylene ether compound would result in combination of dielectric characteristics such as low dielectric constant and low dielectric loss tangent, and high heat resistance.

More specific examples of the modified polyphenylene ether compound include modified polyphenylene ether compounds represented by formulas (1) and (2).

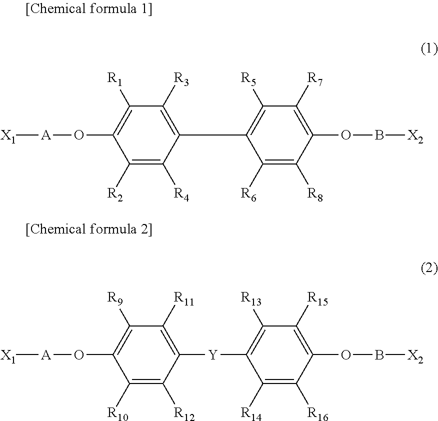

In formulas (1) and (2), R₁ to R₈ and R₉ to R₁₆ are independent from each other, That is, Rᵢ to R₈ and R₉ to R₁₆ may be the same group or different groups. R₁ to R₈, and R₉ R₁₆ represent a hydrogen atom, an alkyl group, an alkenyl group, an alkynyl group, a formyl group, an alkylcarbonyl group, an alkenylcarbonyl group, or an alkynylcarbonyl group. Among these, a hydrogen atom and an alkyl group are preferred.

Regarding R₁ to R₈ and R₉ to R₁₆, specific examples of the functional groups recited above include the following.

Although the alkyl group is not particularly limited, for example, the alkyl group is preferably an alkyl group having 1 to 18 carbon atoms, and more preferably an alkyl group having l to 10 carbon atoms. Specific examples include a methyl group, an ethyl group, a propyl group, a hexyl group, and a decyl group.

Although the alkenyl group is not particularly limited, for example, the alkenyl group is preferably an alkenyl group having 2 to 18 carbon atoms, and more preferably an alkenyl group having 2 to 10 carbon atoms. Specific examples include a vinyl group, an allyl group, and a 3-butenyl group.

Although the alkynyl group is not particularly limited, for example, the alkynyl group is preferably an alkynyl group having 2 to 18 carbon atoms, and more preferably an alkynyl group having 2 to 10 carbon atoms. Specific examples include an ethynyl group, and a prop-2-yn-1-yl group (propargyl group).

Although the alkylcarbonyl group is not particularly limited as long as it is a carbonyl group substituted with an alkyl group, for example, the alkylcarbonyl group is preferably an alkylcarbonyl group having 2 to 18 carbon atoms, and more preferably an alkylcarbonyl group having 2 to 10 carbon atoms. Specific examples include an acetyl group, a propionyl group, a butyryl group, an isobutyryl group, a pivaloyl group, a hexanoyl group, an octanoyl group, and a cyclohexylcarbonyl group.

Although the alkenylcarbonyl group is not particularly limited as long as it is a carbonyl group substituted with an alkenyl group, for example, the alkenylcarbonyl group is preferably an alkenylcarbonyl group having 3 to 18 carbon atoms, and more preferably an alkenylcarbonyl group having 3 to 10 carbon atoms. Specific examples include an acryloyl group, a methacryloyl group and a crotonoyl group.

Although the alkynylcarbonyl group is not particularly limited as long as it is a carbonyl group substituted with an alkynyl group, for example, the alkynylcarbonyl group is preferably an alkynylcarbonyl group having 3 to 18 carbon atoms, and more preferably an alkynylcarbonyl group having 3 to 10 carbon atoms. Specific examples include a propioloyl group.

In formulas (1) and (2), A and B are structures respectively shown by formulas (3) and (4), as described above.

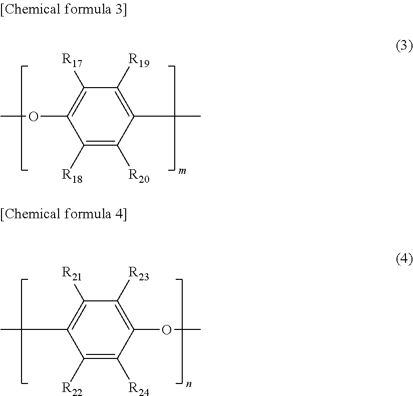

In formulas (3) and (4), m and n which are repeating units respectively represent an integer of 1 to 50.

R₁₇ to R₂₀ and R₂₁ to R₂₄ are independent from each other. That is, Rᵢg to R₂₀ and R₂₁ to R₂₄ may be the same group or different groups. In the present embodiment, R₁₇ to R₂₀ and R₂₁ to R₂₄ each represent a hydrogen atom or an alkyl group.

Further, in formula (2), examples of Y include linear, branched or cyclic hydrocarbons having 20 or less carbon atoms. More specifically, examples include structures represented by formula (5).

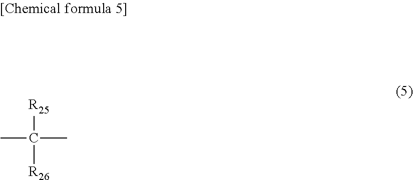

In formula (5), R₂₅ and R₂₆ each independently represent a hydrogen atom or an alkyl group. Examples of the alkyl group include a methyl group. Examples of the group represented by formula (5) include a methylene group, a methylmethylene group, and a dimethylmethylene group.

In formulas (1) and (2), it is preferred that X₁ and X2 each independently represent a substituent having a carbon-carbon unsaturated double bond as represented by formula (6) or (7). X₁ and X₂ may be the same or different from each other.

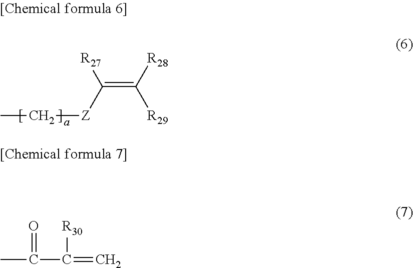

In formula (6), a represents an integer of 0 to 10. In formula (7), when a is 0, Z represents a moiety directly binding with a terminal of polyphenylene ether.

In formula (6), Z represents an arylene group. The arylene group is not particularly limited. Specific examples include monocyclic aromatic groups such as a phenylene group, and polycyclic aromatic groups in which the aromatic ring is not monocyclic but is polycyclic aromatic such as a naphthalene ring. The arylene group includes derivatives in which the hydrogen atom binding to the aromatic ring is substituted with a functional group such as an alkenyl group, an alkynyl group, a formyl group, an alkylcarbonyl group, an alkenylcarbonyl group, or an alkynylcarbonyl group.

In formula (6), R₂₇ to R₂₉ each may independently be the same group or different groups, and each represent a hydrogen atom or an alkyl group. The alkyl group is not particularly limited, and, for example, the alkyl group is preferably an alkyl group having 1 to 18 carbon atoms, and more preferably an alkyl group having 1 to 10 carbon atoms. Specific examples include a methyl group, an ethyl group, a propyl group, a hexyl group, and a decyl group.

Preferred specific examples of the substituent represented by formula (6) include functional groups including a vinylbenzyl group.

In formula (7), R₃₀ represents a hydrogen atom or an alkyl group. The alkyl group is not particularly limited, and, for example, the alkyl group is preferably an alkyl group having 1 to 18 carbon atoms, and more preferably an alkyl group having 1 to 10 carbon atoms. Specific examples include a methyl group, an ethyl group, a propyl group, a hexyl group, and a decyl group.

More specific examples of the substituents X₁ and X₂ in the present embodiment include vinylbenzyl groups (ethenylbenzyl group) such as a p-ethenylbenzyl group and an m-ethenylbenzyl group, a vinylphenyl group, an acrylate group, and a methacrylate group.

Use of the modified polyphenylene ether compounds represented by formulas (1) and (2) would result in combination of excellent heat resistance in addition to low dielectric characteristics such as low dielectric constant and low dielectric loss tangent, and high Tg and adhesiveness.

The modified polyphenylene ether compounds represented by formulas (1) and (2) may be used singly or in combination of two or more kinds.

In the present embodiment, although not particularly limited, for example, the weight average molecular weight (Mw) of the modified polyphenylene ether compound is preferably 1000 to 5000, and more preferably 1000 to 4000. The weight average molecular weight can be measured by an ordinary molecular weight measuring method, and is specifically, a value measured by gel permeation chromatography (GPC) and so on are recited. When the modified polyphenylene ether compound has a repeating unit (s, m, n) in the molecule, it is preferred that the repeating unit is a numerical value with which the weight average molecular weight of the modified polyphenylene ether compound falls within the above range.

When the weight average molecular weight of the modified polyphenylene ether compound falls within the above range, excellent low dielectric characteristics peculiar to the polyphenylene ether is endowed, and more excellent resistance of the cured product, and excellent moldability are achieved. This would owe to the following reasons. In a normal polyphenylene ether, a polyphenylene ether having a weight average molecular weight falling within the above range has a relatively low molecular weight, so that the heat resistance of the cured product of the polyphenylene ether tends to decrease. In this respect, the modified polyphenylene ether compound according to the present embodiment has an unsaturated double bond at a terminal, and has high reactivity, and thus the cured product would have sufficiently high heat resistance. When the weight average molecular weight of the modified polyphenylene ether compound falls within the above range, the modified polyphenylene ether compound has relatively low molecular weight, and has low melt viscosity and excellent moldability would be achieved. Therefore, such a modified polyphenylene ether compound would give excellent moldability and appearance as well as more excellent heat resistance of the cured product.

An average number of substituents (the number of terminal functional groups) in a molecule terminal per one molecule of the modified polyphenylene ether in the modified polyphenylene ether compound used in the present embodiment is not particularly limited. Specifically, the average number of substituents is preferably 1 to 5, and more preferably 1 to 3. If the number of terminal functional groups is too small, there is a tendency that Tg decreases, and sufficient heat resistance of the cured product is difficult to be obtained. If the number of terminal functional groups is too large, the reactivity is too high, and, for example, the problems of deterioration in storage stability of the resin composition, and deterioration in fluidity of the resin composition can occur due to increase in melt viscosity. That is, when such a modified polyphenylene ether is used, for example, molding defect such as generation of voids can occur at the time of multi-layer molding due to the insufficient fluidity or the like, and this can cause the problem in moldability of difficulty in obtaining a reliable printed wiring board.

The number of terminal functional groups of the modified polyphenylene ether compound can be a numerical value showing an average number of substituents per one molecule of all the modified polyphenylene ether compound existing in 1 mole of the modified polyphenylene ether compound. The number of terminal functional groups can be determined, for example, by measuring the number of hydroxyl groups remaining in the obtained modified polyphenylene ether compound, and calculating a decrement from the number of hydroxyl groups of the polyphenylene ether before modification. The decrement from the number of hydroxyl groups of the polyphenylene ether before modification is the number of terminal functional groups. The method for measuring the number of hydroxyl groups remaining in the modified polyphenylene ether compound may include adding a quaternary ammonium salt that associates with a hydroxyl group (tetraethylammonium hydroxide) to a solution of the modified polyether ether compound, and measuring the UV absorbance of the mixed solution.

Also, the intrinsic viscosity of the modified polyphenylene ether compound used in the present embodiment is not particularly limited. Specifically, the intrinsic viscosity may be 0.03 to 0.12 dl/g, preferably 0.04 to 0.11 dl/g, and more preferably 0.06 to 0.095 dl/g. If the intrinsic viscosity is too low, the molecular weight tends to be low, and low dielectricity such as low dielectric constant and low dielectric loss tangent tends to be difficult to be obtained. If the intrinsic viscosity is too high, the viscosity is high, and sufficient fluidity is not obtained, and the moldability of the cured product tends to decrease. Therefore, when the intrinsic viscosity of the modified polyphenylene ether compound falls within the above range, excellent heat resistance and moldability of the cured product can be realized.

The intrinsic viscosity in the present description is an intrinsic viscosity measured in methylene chloride at 25° C., and more specifically, for example, a measurement value of a 0.18 g/45 ml methylene chloride solution (liquid temperature 25° C.) measured with a viscometer. As the viscometer, for example, AVS500 Visco System available from Schott can be recited.

A method for synthesizing the modified polyphenylene ether compound preferably used in the present embodiment is not particularly limited as long as a modified polyphenylene ether compound that is terminally modified with substituents X₁ and X₂ as described above can be synthesized. Specifically, a method of reacting a compound in which substituents X₁ and X₂ and a halogen atom are bound, with polyphenylene ether can be recited.

The polyphenylene ether that is a starting material is not particularly limited as long as a specific modified polyphenylene ether can be finally synthesized. Specific examples include a polyphenylene ether composed of 2,6-dimethylphenol, and at least one of a bifunctional phenol and a trifunctional phenol, and those based on polyphenylene ether, such as poly(2,6-dimethyl-1,4-phenylene oxide). The bifunctional phenol means a phenol compound having two phenolic hydroxyl groups in each molecule, and, for example, tetramethylbisphenol A can be recited. The trifunctional phenol means a phenol compound having three phenolic hydroxyl groups in each molecule.

As one example of a method for synthesizing a modified polyphenylene ether compound, for example, in the case of the modified polyphenylene ether compound represented by formula (2), specifically, a polyphenylene ether as described above, and a compound in which substituents X₁ and X₂ and a halogen atom are bound (compound having substituents X₁ and X₂) are dissolved in the solvent and stirred. Thus, the polyphenylene ether, and the compound having substituents X₁ and X₂ react, and the modified polyphenylene ether represented by formula (2) in the present embodiment is obtained.

It is preferred that the reaction is conducted in the presence of an alkali metal hydroxide. This would allow desired progression of the reaction. This is ascribable to that the alkali metal hydroxide functions as a dehalogenation agent, specifically as a dehydrochlorination agent. In other words, the alkali metal hydroxide eliminates hydrogen halide from the compound having a phenol group of polyphenylene ether and substituent X, and thus the substituents X₁ and X₂ would bind to the oxygen atom of the phenol group in place of the hydrogen atom of the phenol group of the polyphenylene ether.

Although the alkali metal hydroxide is not particularly limited as long as it can serve as a dehalogenation agent, for example, sodium hydroxide is recited. The alkali metal hydroxide is usually used in the form of an aqueous solution, and specifically, used in the form of a sodium hydroxide aqueous solution.

The reaction conditions including the reaction time and the reaction temperature differ depending on the compound having substituents X₁ and X₂, and are not particularly limited as long as the aforementioned reaction progresses desirably. Specifically, the reaction temperature is preferably room temperature to 100° C., and more preferably 30 to 100° C. The reaction time is preferably 0.5 to 20 hours, and more preferably 0.5 to 10 hours.

The solvent used in the reaction is not particularly limited as long as it can dissolve polyphenylene ether, and the compound having substituents X₁ and X₂, and does not inhibit reaction between the polyphenylene ether, and the compound having substituents X₁ and X₂. Specific examples include toluene.

It is preferred that the aforementioned reaction is conducted in the presence of a phase transfer catalyst in addition to the alkali metal hydroxide. In other words, it is preferred that the aforementioned reaction is conducted in the presence of an alkali metal hydroxide and a phase transfer catalyst. This would allow more desired progression of the reaction. This would owe to the following reasons. This is ascribable to that the phase transfer catalyst is a catalyst that has a function of taking in the alkali metal hydroxide, and is soluble both in a phase of a polar solvent such as water, and in a phase of a nonpolar solvent such as an organic solvent, and is movable between these phases. Specifically, in the case where a sodium hydroxide aqueous solution is used as an alkali metal hydroxide, and an organic solvent such as toluene that is immiscible to water is used as a solvent, the solvent and the sodium hydroxide aqueous solution separate from each other even when the sodium hydroxide aqueous solution is dropped to the solvent being subjected to the reaction, and sodium hydroxide is difficult to migrate to the solvent. In such a case, the sodium hydroxide aqueous solution added as the alkali metal hydroxide would be less likely to contribute to acceleration of the reaction. On the other hand, when the reaction is conducted in the presence of the alkali metal hydroxide and the phase transfer catalyst, the alkali metal hydroxide migrates to the solvent while the alkali metal hydroxide is taken in the phase transfer catalyst, and the sodium hydroxide aqueous solution would be more likely to contribute to acceleration of the reaction. Therefore, the reaction would progress more desirably when the reaction is conducted in the presence of the alkali metal hydroxide and the phase transfer catalyst.

Although the phase transfer catalyst is not particularly limited, for example, quaternary ammonium salts such as tetra-n-butylammonium bromide are recited.

It is preferred that the resin composition according to the present embodiment contains a modified polyphenylene ether obtained in the manner as described above as the modified polyphenylene ether.

The resin composition of the present embodiment may contain a thermosetting resin other than the polyphenylene ether compound as described above. Examples of such other thermosetting resins that can be used include an epoxy resin, a phenol resin, an amine resin, an unsaturated polyester resin, and a thermosetting polyimide resin.

### Maleimide Compound

Next, a maleimide compound used in the present embodiment is described. The maleimide compound used in the present embodiment is not particularly limited as long as it is a maleimide compound having two or more N-substituted maleimide groups in one molecule. Since such a maleimide compound efficiently reacts with the modified polyphenylene ether compound, high heat resistance is obtained. The maleimide compound contributes to high Tg, low CTE (coefficient of thermal expansion) and low dielectric characteristics in a cured product of the resin composition.

Although a functional group equivalent of the maleimide group of the maleimide compound used in the present embodiment is not particularly limited, the functional group equivalent is desirably 130 to 500 g/eq., more desirably 200 to 500 g/eq., and further desirably 230 to 400 g/eq. When the functional group equivalent falls within the above range, Tg of the cured product would be increased, and water absorption would be lowered more reliably.

Although the above-described maleimide compound is not particularly limited, more specifically, maleimide compounds represented by formulas (8) to (15) are recited as preferred examples. These may be used singly or in combination of two or more kinds.

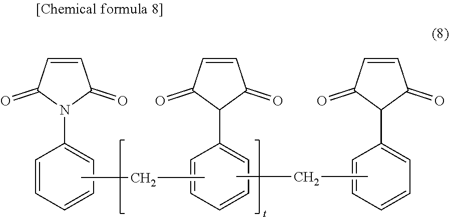

In formula (8), t, which is a repeating unit, is 0.1 to 10.

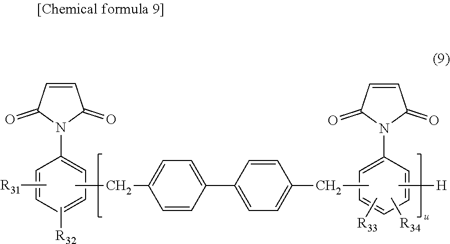

In formula (9), u, which is a repeating unit, is an average value, and is more than 1 and 5 or less. R₃₁ to R₃₄ each independently represent a group selected from the group consisting of a hydrogen atom, an alkyl group having 1 to 5 carbon atoms, and a phenyl group.

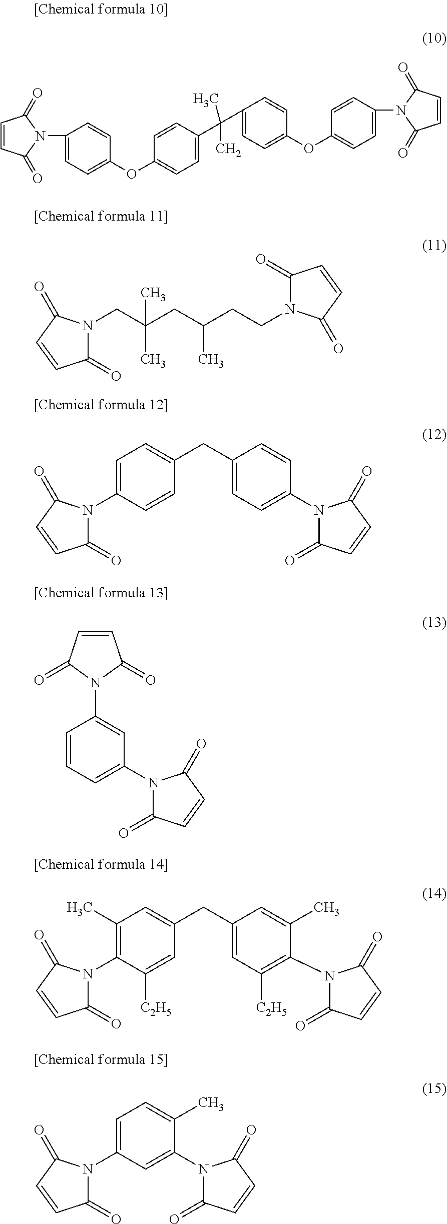

As such a maleimide compound, a commercially available product may be used, and for example, BMI-4000, BMI-2300, BMI-TMH and the like available from Daiwakasei Industry Co., Ltd., or MIR-3000 and the like available from Nippon Kayaku Co., Ltd. may be used.

The content of the maleimide compound is preferably 5 to 50 parts by mass per 100 parts by mass of a total of the modified polyphenylene ether compound, the maleimide compound, and the styrene-based polymer. By containing the maleimide compound within the above range, high Tg and low water absorption would be achieved more reliably. More preferably, the content of the maleimide compound is 5 to 40 parts by mass, and further desirably, 10 to 40 parts by mass.

### Styrene-Based Polymer

Next, a styrene-based polymer used in the present embodiment is described. The styrene-based polymer used in the present embodiment is not particularly limited as long as it is a styrene-based polymer having a weight average molecular weight of less than 10000.

Since the styrene-based polymer having such a molecular weight has relatively small molecular weight, the melt viscosity is low, the resin flowability of the resin composition is excellent, and the moldability can be improved. Further, since the molecular weight is relatively small, the styrene-based polymer having a hydrophobic backbone shows high solubility in a polar solvent such as methylethylketone as well as in a hydrophobic solvent such as toluene or hexane. Therefore, it is possible to easily prepare a varnishy resin composition (resin varnish) with the maleimide compound having a polar group using methylethylketone. Also, the dielectric characteristics of the resin composition can be improved owing to the styrene-based polymer.

As the styrene-based polymer that is used in the present embodiment, those conventionally known can be widely used, and specific examples of the styrene-based polymer include, but are not limited to, polymers or copolymers that are obtained by polymerizing or copolymerizing one or more kinds of styrene-based monomers such as styrene, styrene derivatives, styrene in which part of hydrogen atoms in the benzene ring is substituted with an alkyl group, styrene in which part of hydrogen atoms in the vinyl group is substituted with an alkyl group, vinyltoluene, α-methylstyrene, and isopropenyltoluene.

As the styrene-based monomer, specifically, those having the structures represented by formulas (16) and (17) are recited as preferred examples.

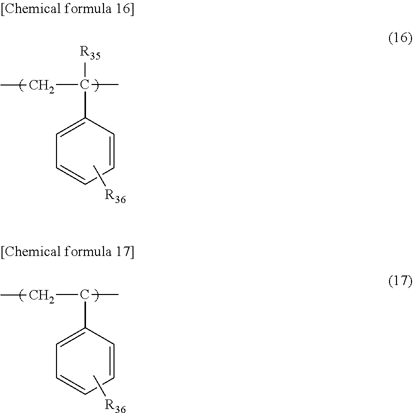

In formulas (16) and (17), R₃₅ to R₃₇ each may independently be the same group or different groups, and each represent a hydrogen atom or an alkyl group. The alkyl group is not particularly limited, and, for example, the alkyl group is preferably an alkyl group having 1 to 18 carbon atoms, and more preferably an alkyl group having 1 to 10 carbon atoms. Specific examples include a methyl group, an ethyl group, a propyl group, a hexyl group, and a decyl group.

As a styrene-based copolymer, a copolymer obtained by copolymerizing one or more kinds of styrene-based monomers as described above, and one or two or more kinds of other monomers copolymerizable with the styrene-based monomers may be used. Examples of the copolymerizable monomers include olefins such as α-pinene, β-pinene, and dipentene, and unsaturated compounds such as unconjugated dienes.

For examples, monomers containing the structure represented by formula (18) are recited as other copolymerizable monomers.

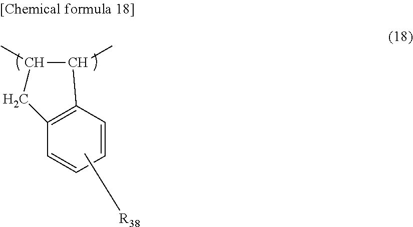

R₃₈ represents the same group as described for R₃₅ to R₃₇.

As such a styrene-based polymer, a commercially available product may be used, and for example, FTR (registered trade name) series or FMR series available from Mitsui Chemicals, Inc., SX-100 available from YASUHARA CHEMICAL CO., LTD. and the like may be used.

The styrene-based polymers may be used singly or in combination of two or more kinds.

Although not particularly limited, it is desired that the weight average molecular weight of the styrene-based polymer of the present embodiment is preferably about 1000 to 9000. If the molecular weight is too small, the styrene-based polymer can volatilize in the step of drying the resin varnish, or heat resistance of the cured product of the resin composition can deteriorate. If the molecular weight is too large, there would be a possibility that the melt viscosity increases, and the moldability deteriorates. The molecular weight is more preferably 1000 to 7000, further preferably 1000 to 5000, and further desirably about 1000 to 4000.

The content of the styrene-based polymer is preferably 5 to 50 parts by mass per 100 parts by mass of a total of the modified polyphenylene ether compound, the maleimide compound, and the styrene-based polymer. By containing the styrene-based polymer within the above range, it would be possible to achieve high Tg, low CTE and low dielectric characteristics more reliably. The content of the styrene-based polymer is more preferably 5 to 40 parts by mass, and further desirably 5 to 20 parts by mass.

### Content Ratio of Components

In the resin composition of the present embodiment, the content ratio between the modified polyphenylene ether compound and the maleimide compound is 95:5 to 25:75 in a mass ratio. If the ratio of the content of the modified polyphenylene ether compound is smaller than the above, there is a possibility that adhesion with a copper foil decreases. On the other hand, if the ratio of the content of the maleimide compound is smaller than the above, there is a possibility that Tg decreases, and heat resistance deteriorates.

The range of content ratio between the modified polyphenylene ether compound and the maleimide compound is more preferably 90:10 to 30:70, and further preferably 90:10 to 50 : 50.

### Other Components

The resin composition according to the present embodiment may further contain other component besides the modified polyphenylene ether compound, the maleimide compound, and the styrene-based polymer.

The resin composition according to the present embodiment may further contain, for example, a curing agent. The curing agent is not particularly limited as long as it is a curing agent capable of reacting with the polyphenylene ether compound to cure the resin composition containing the polyphenylene ether compound. As the curing agent, for example, a curing agent having at least one functional group contributing to the reaction with the polyphenylene ether compound in the molecule is recited. Examples of the curing agent include styrene, a styrene derivative, a compound having an acryloyl group in the molecule, a compound having a methacryloyl group in the molecule, a compound having a vinyl group in the molecule, a compound having an allyl group in the molecule, a compound having an acenaphthylene structure in the molecule, and an isocyanurate compound having an isocyanurate group in the molecule.

Examples of the styrene derivative include bromostyrene and dibromostyrene, and divinylbenzene.

The compound having an acryloyl group in the molecule is an acrylate compound. Examples of the acrylate compound include a monofunctional acrylate compound having one acryloyl group in the molecule, and a multifunctional acrylate compound having two or more acryloyl groups in the molecule. Examples of the monofunctional acrylate compound include methyl acrylate, ethyl acrylate, propyl acrylate, and butyl acrylate. Examples of the multifunctional acrylate compound include tricyclodecanedimethanol diacrylate.

The compound having a methacryloyl group in the molecule is a methacrylate compound. Examples of the methacrylate compound include a monofunctional methacrylate compound having one methacryloyl group in the molecule, and a multifunctional methacrylate compound having two or more methacryloyl groups in the molecule. Examples of the monofunctional methacrylate compound include methyl methacrylate, ethyl methacrylate, propyl methacrylate, and butyl methacrylate. Examples of the multifunctional methacrylate compound include tricyclodecanedimethanol dimethacrylate.

The compound having a vinyl group in the molecule is a vinyl compound. Examples of the vinyl compound include a monofunctional vinyl compound having one vinyl group in the molecule, and a multifunctional vinyl compound having two or more vinyl groups in the molecule. Examples of the multifunctional vinyl compound include divinylbenzene and polybutadiene.

The compound having an allyl group in the molecule is an allyl compound. Examples of the allyl compound include a monofunctional allyl compound having one allyl group in the molecule, and a multifunctional allyl compound having two or more allyl groups in the molecule. Examples of the multifunctional allyl compound include diallyl phthalate (DAP).

The compound having an acenaphthylene structure in the molecule is an acenaphthylene compound. Examples of the acenaphthylene compound include acenaphthylene, alkylacenaphthylenes, halogenated acenaphthylenes, and phenylacenaphthylenes. Examples of the alkylacenaphthylenes include 1-methylacenaphthylene, 3-methylacenaphthylene, 4-methylacenaphthylene, 5-methylacenaphthylene, 1-ethylacenaphthylene, 3-ethylacenaphthylene, 4-ethylacenaphthylene, and 5-ethylacenaphthylene. Examples of the halogenated acenaphthylenes include 1-chloroacenaphthylene, 3-chloroacenaphthylene, 4-chloroacenaphthylene, 5-chloroacenaphthylene, 1-bromoacenaphthylene, 3-bromoacenaphthylene, 4-bromoacenaphthylene, and 5-bromoacenaphthylene. Examples of the phenylacenaphthylenes include 1-phenylacenaphthylene, 3-phenylacenaphthylene, 4-phenylacenaphthylene, and 5-phenylacenaphthylene. The acenaphthylene compound may be a monofunctional acenaphthylene compound having one acenaphthylene structure in the molecule, or a multifunctional acenaphthylene compound having two or more acenaphthylene structures in the molecule.

The compound having an isocyanurate group in the molecule is an isocyanurate compound. As the isocyanurate compound, a compound further having an alkenyl group in the molecule (alkenyl isocyanurate compound), for example, a trialkenyl isocyanurate compound such as triallyl isocyanurate (TRIC) are recited.

Preferred examples of the curing agent among those recited above include a multifunctional acrylate compound having two or more acryloyl groups in the molecule, a multifunctional methacrylate compound having two or more methacryloyl groups in the molecule, a multifunctional vinyl compound having two or more vinyl groups in the molecule, a styrene derivative, an allyl compound having an allyl group in the molecule, a maleimide compound having a maleimide group in the molecule, an acenaphthylene compound having an acenaphthylene structure in the molecule, and an isocyanurate compound having an isocyanurate group in the molecule.

Particularly preferably, it is desired to contain a trialkenyl isocyanurate compound such as triallyl isocyanurate (TAIC) as the curing agent. This makes it possible to control the fluidity at the time of melting of the resin, and has the advantage of being capable of decreasing the void risk in the molding step.

The curing agent may be used singly or in combination of two or more kinds.

The weight average molecular weight of the curing agent is preferably 100 to 5000, more preferably 100 to 4000, and further preferably 100 to 3000. If the weight average molecular weight of the curing agent is too low, there is a possibility that the curing agent becomes easy to volatilize from the blended component system of the resin composition. If the weight average molecular weight of the curing agent is too high, there is a possibility that the viscosity of the varnish of the resin composition, and the melt viscosity at the time of heat molding are too high. Therefore, when the weight average molecular weight of the curing agent falls within the above range, a resin composition that is more excellent in heat resistance of a cured product is obtained. This is ascribable to that the reaction with the modified polyphenylene ether compound can favorably cure the resin composition containing the modified polyphenylene ether compound. The weight average molecular weight can be measured by an ordinary molecular weight measuring method, and is specifically, a value measured by gel permeation chromatography (GPC) and so on are recited.

In the curing agent, although an average number of the functional groups contributing to the reaction with the modified polyphenylene ether compound per one molecule of the curing agent (a number of functional groups) differs depending on the weight average molecular weight of the curing agent, for example, the number of functional groups is preferably 1 to 20, and more preferably 2 to 18. If the number of functional groups is too small, there is a tendency that sufficient heat resistance of the cured product is difficult to be obtained. If the number of functional groups is too large, the reactivity is too high, and, for example, the problems of deterioration in storage stability of the resin composition, and deterioration in fluidity of the resin composition can occur.

Besides the above, for example, the resin composition according to the present embodiment may further contain a filler. Examples of the filler include, but are not limited to, those added for enhancing the heat resistance and the incombustibility of the cured product of the resin composition. By containing the filler, it is possible to further enhance the heat resistance, the incompatibility, and the so on. Specific examples of the filler include metal oxides including silica such as spherical silica, alumina, titanium oxide, and mica, metal hydroxides such as aluminum hydroxide, and magnesium hydroxide, talc, aluminum borate, barium sulfate, and calcium carbonate. Among these, silica, mica, and talc are preferred, and spherical silica is more preferred as the filler. The filler may be used singly or in combination of two or more kinds. The filler may be used as it is, or may be used while it is surface-treated with a silane coupling agent of epoxy silane type, vinyl silane type, methacryl silane type, or amino silane type. The silane coupling agent may be added by an integral blending method rather than by the method of preliminarily subjecting the filler to a surface treatment.

When the filler is contained, the content of the filler is preferably 10 to 200 parts by mass, more preferably 30 to 150 parts by mass per 100 parts by mass of a total of the organic component (the modified polyphenylene ether compound, the maleimide compound, and the styrene-based polymer).

The resin composition of the present embodiment may further contain a flame retarder, and examples of the flame retarder include halogen-based flame retarders such as a bromine-based flame retarder, and phosphorus-based flame retarders. Specific examples of the halogen-based flame retarders include bromine-based flame retarders such as pentabromodiphenylether, octabromodiphenylether, decabromodiphenylether, tetrabromobisphenol A, and hexabromocyclododecane, and chlorine-based flame retarders such as chlorinated paraffin. Specific examples of the phosphorus-based flame retarders include phosphate esters such as condensed phosphate esters, and cyclic phosphate esters, phosphazene compounds such as cyclic phosphazene compounds, phosphinate-based flame retarders such as phosphinic acid metal salts such as dialkylphosphinic acid aluminum salts, melamine-based flame retarders such as melamine phosphate and melamine polyphosphate, and phosphine oxide compounds having a diphenylphosphine oxide group. The flame retarder may be used singly or in combination of two or more kinds from the exemplified flame retarders.

Further, the resin composition according to the present embodiment may further include additives besides the above. Examples of the additives include an antifoaming agent such as a silicone-based antifoaming agent and an acry late ester-based antifoaming agent, a heat stabilizer, an antistatic agent, a ultraviolet absorber, a dye, a pigment, a lubricant, and a dispersing agent such as a wetting and dispersing agent.

The resin composition according to the present embodiment may further contain a reaction initiator. Although the curing reaction can proceed only by the modified polyphenylene ether compound, the maleimide compound, and the styrene-based polymer, a reaction initiator may be added because it is sometimes difficult to raise the temperature to temperatures at which the curing proceeds depending on the process conditions. The reaction initiator is not particularly limited as long as it can accelerate the curing reaction between the modified polyphenylene ether compound and the maleimide compound. Specific examples include oxidizing agents such as α,α′-bis(t-butylperoxy-m-isopropyl)benzene, 2,5-dimethyl-2,5-di(t-butylperoxy)-3-hexyne, benzoyl peroxide, 3,3′,5,5′-tetramethyl-1,4-diphenoquinone, chloranil, 2,4,6-tri-t-butylphenoxyl, t-butylperoxyisopropylmonocarbonate, and azobisisobutyronitrile. Also, a carboxylic acid metal salt or the like can be used together as needed. This further accelerates the curing reaction. Among these, α,α′-bis(t-butylperoxy-m-isopropyl)benzene is preferably used. Since α,α′-bis(t-butylperoxy-m-isopropyl)benzene has a relatively high reaction initiation temperature, it is possible to control acceleration of the curing reaction when curing is not required, for example at the time of drying of a prepreg, and it is possible to control deterioration in storage stability of the resin composition. Further, since α,α′-bis(t-butylperoxy-m-isopropyl)benzene has low volatility, volatilization does not occur at the time of drying or during storage of a prepreg, a film or the like, and excellent stability is achieved. The reaction initiator may be used singly or in combination of two or more kinds. Regarding the content, the reaction initiator is used such that an adding amount of the reaction initiator is 0.1 to 2 parts by mass per 100 parts by mass of a total of the modified polyphenylene ether compound, the maleimide compound, and the styrene-based polymer.

### Prepreg, Film with Resin, Metal-Clad Laminate, Wiring Board, and Metal Foil with Resin

Next, a prepreg, a metal-clad laminate, a wiring board, and a metal foil with resin using the resin composition of the present embodiment are described. Principal reference signs in the later-described drawings denote as follows: 1 prepreg, 2 resin composition or semi-cured product of resin composition, 3 fibrous base material, 11 metal-clad laminate, 12 insulating layer, 13 metal foil, 14 wiring, 21 wiring board, 31 metal foil with resin, 32, 42 resin layers, 41 film with resin, 43 support film.

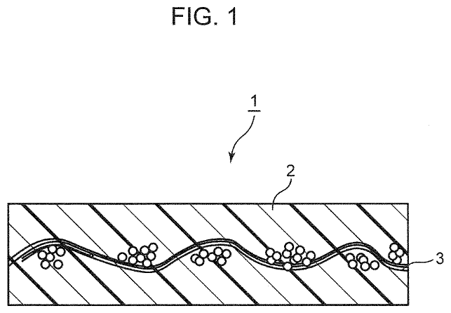

FIG. 1 is a schematic section view showing one example of the prepreg 1 according to an embodiment of the present invention.

As shown in FIG. 1, the prepreg 1 according to the present embodiment includes the resin composition or the semi-cured product of the resin composition 2, and the fibrous base material 3. In one example of the prepreg 1, the fibrous base material 3 exists in the resin composition or the semi-cured product thereof 2. That is, the prepreg 1 includes the resin composition or the semi-cured product thereof, and the fibrous base material 3 existing in the resin composition or the semi-cured product thereof 2.

In the present embodiment, “semi-cured product” means a product in the state that the resin composition is cured halfway to such an extent that the resin composition can be further cured. That is, the semi-cured product is in such a state that the resin composition is semi-cured (B-staged). For example, as the resin composition is heated, the resin composition gradually becomes less viscous in the beginning, and then starts curing, and gradually becomes more viscous. In such a case, as a “semi-cured” state, the state before completion of curing after starting of increase in viscosity can be recited.

A prepreg obtained by using the resin composition according to the present embodiment may include the semi-cured product of the resin composition, or may include the resin composition itself that is not cured. That is, the prepreg may be a prepreg including the semi-cured product of the resin composition (the resin composition in B stage) and a fibrous base material, or may be a prepreg including the resin composition before curing (the resin composition in A stage) and a fibrous base material. Specific examples include prepregs in which the fibrous base material exists in the resin composition. The resin composition or the semi-cured product thereof may be the resin composition that is heat dried.

The resin composition according to the present embodiment is often prepared into varnish, and used as resin varnish in production of the prepreg, or the later-described metal foil with resin, metal-clad laminate, and so on. Such resin varnish is prepared, for example, in the following manner.

First, components that are soluble in an organic solvent, such as a modified polyphenylene ether compound, a maleimide compound, a styrene-based polymer, and a reaction initiator, are introduced and dissolved in the organic solvent. At this time, heating may be conducted as needed. Then, a component that is insoluble in the organic solvent, for example, an inorganic filler is added, and then the component is dispersed until a predetermined dispersed state is achieved with a ball mill, a beads mill, a planetary mixer, a roll mill or the like, and thus a varnishy resin composition is prepared. The organic solvent used herein is not particularly limited as long as it dissolves the modified polyphenylene ether compound, the maleimide compound, the styrene-based polymer and so on, and it does not inhibit the curing reaction. Specific examples include toluene, methylethylketone, cyclohexanone, and propylene glycol monomethyl ether acetate. These may be used singly or in combination of two or more kinds.

The resin varnish of the present embodiment is advantageous in that it is excellent in film flexibility, film formability, and impregnating ability to glass cloth, and it is easy to handle.

As a method for producing the prepreg 1 of the present embodiment using the varnishy resin composition of the present embodiment, for example, a method of impregnating the fibrous base material 3 with the resin varnishy resin composition 2, followed by drying is recited.

Specific examples of the fibrous base material used in producing a prepreg include glass cloth, aramid cloth, polyester cloth, LCP (liquid crystal polymer) nonwoven fabric, glass nonwoven fabric, aramid nonwoven fabric, polyester nonwoven fabric, pulp paper, and linter paper. A laminate having excellent mechanical strength is obtained by using glass cloth, and in particular, glass cloth that is subjected to a flattening process is preferred. Although the glass cloth for use in the present embodiment is not particularly limited, for example, glass cloth having low dielectric constant such as E glass, S glass, NE glass, Q glass, and L glass can be recited. The flattening process can be performed, specifically, for example, by compressing yarns into flat by continuously pressurizing the glass cloth at an appropriate pressure by means of a press roll. As the fibrous base material, for example, those having a thickness of 0.01 to 0.3 mm can be generally used.

Impregnation of the fibrous base material 3 with the resin varnish (resin composition 2) is performed by dipping, coating and so on. The impregnation can be repeated plural times as needed. In this case, by repeating impregnation using a plurality of resin varnishes having different compositions or concentrations, a desired composition (content ratio) and a desired resin amount can be eventually achieved.

The fibrous base material 3 impregnated with the resin varnish (resin composition 2) is heated in desired heating conditions, for example, at 80° C. or more and 180° C. or less for 1 minute or more and 10 minutes or less. The solvent is volatilized from the varnish by heating, and the solvent is reduced or removed to give the prepreg 1 before curing (A stage) or in a semi-cured state (B stage).

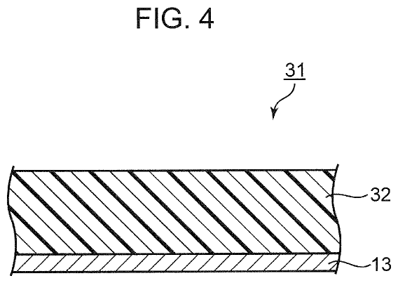

Also, as shown in FIG. 4, the metal foil with resin 31 of the present embodiment has such a configuration that the resin layer 32 containing the aforementioned resin composition or the semi-cured product of the resin composition, and the metal foil 13 are laminated. That is, the metal foil with resin of the present embodiment may be a metal foil with resin including a resin layer containing the resin composition before curing (the resin composition of A stage), and a metal foil, or may be a metal foil with resin including a resin layer containing the semi-cured product of the resin composition (the resin composition of B stage), and a metal foil.

As a method for producing the metal foil with resin 31, for example, a method of coating the surface of the metal foil 13 such as a copper foil with the aforementioned resin varnishy resin composition, followed by drying is recited. Examples of the coating method include a bar coater, a comma coater, a die coater, a roll coater, and a gravure coater.

As the metal foil 13, metal foils used in a metal-clad laminate or a wiring board can be used without limitation, and for example, copper foil, aluminum foil, and so on are recited.

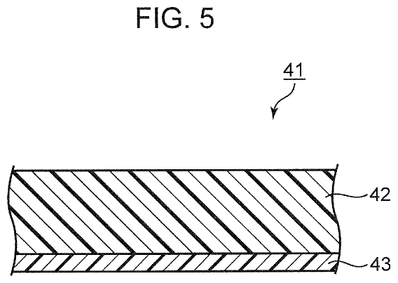

Further, as shown in FIG. 5, the film with resin 41 of the present embodiment has such a configuration that the resin layer 42 containing the aforementioned resin composition or the semi-cured product of the resin composition, and the film support base material 43 are laminated. That is, the film with resin of the present embodiment may be a film with resin containing the resin composition before curing (the resin composition of A stage), and a film support base material, or may be a film with resin containing the semi-cured product of the resin composition (the resin composition of B stage), and a film support base material.

As a method for producing the film with resin 41, for example, the surface of the film support base material 43 is coated with the aforementioned resin varnishy resin composition, and then the solvent is volatilized from the varnish to reduce or remove the solvent, and thus a film with resin before curing (A stage) or in the semi-cured state (B stage) can be obtained.

Examples of the film support base material include electric insulating films such as a polyimide film, a PET (polyethylene terephthalate) film, a polyester film, a polyparabanic acid film, a polyetherether ketone film, a polyphenylene sulfide film, an aramid film, a polycarbonate film, and a polyarylate film.

Also in the film with resin and the metal foil with resin of the present embodiment, the resin composition or the semi-cured product thereof may be the resin composition that is dried or heat dried as with the case of the prepreg described above.

The thickness and so on of the metal foil 13 and the film support base material 43 can be appropriately set in accordance with the desired purpose. For example, as the metal foil 13, those having a thickness of about 0.2 to 70 μm can be used. When the thickness of the metal foil is, for example, 10 μm or less, a copper foil with a carrier, having a release layer and a carrier for improvement in handleability may be employed. Application of the resin varnish to the metal foil 13 or the film support base material 43 is performed by coating or the like, and the coating may be repeated plural times as needed. In this case, by repeating coating using a plurality of resin varnishes having different compositions or concentrations, a desired composition (content ratio) and a desired resin amount can be eventually achieved.

Although the drying or heat drying conditions in the production method of the metal foil with resin 31 or the resin film 41 are not particularly limited, the metal foil 13 or the film support base material 43 is coated with the resin varnishy resin composition, and then heating is conducted at desired heating conditions, for example, at 80 to 170° C. for about 1 to 10 minutes to volatile the solvent from the varnish to reduce or remove the solvent, and thus the metal foil with resin 31 or the resin film 41 before curing (A stage) or in the semi-cured state (B stage) is obtained.

The metal foil with resin 31 or the resin film 41 may further include a cover film and so on as needed. By the cover film, contamination and so on can be prevented. Although the cover film is not particularly limited as long as it can be peeled off without impairment of the form of the resin composition, and for example, a polyolefin film, a polyester film, a TPX film, films formed by providing these films with a release agent layer, and paper sheets prepared by laminating these films on a paper base material can be used.

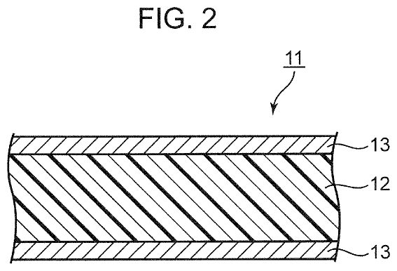

As shown in FIG. 2, the metal-clad laminate 11 of the present embodiment has the insulating layer 12 containing a cured product of the aforementioned resin composition or a cured product of the aforementioned prepreg, and the metal foil 13. As the metal foil 13 for use in the metal-clad laminate 11, the one that is the same as the metal foil 13 described above can be used.

The metal-clad laminate 13 of the present embodiment can also be prepared by using the metal foil with resin 31 or the resin film 41 as described above.

As a method for producing a metal-clad laminate using the prepreg 1, the metal foil with resin 31, or the resin film 41 obtained in the manner as described above, one or a plurality of the prepreg 1, the metal foil with resin 31 or the resin film 41 are stacked, and the metal foil 13 such as a copper foil is stacked on either or both of the upper and lower surfaces, and the stack is heating and pressurizing molded to give an integrated laminate, and thus a double face metal foil-clad laminate or a single face metal foil-clad laminate can be prepared. Although the heating and pressurizing conditions can be appropriately set depending on the thickness of the laminate to be produced, the kind of the resin composition and so on, for example, the temperature can be 170 to 220° C., the pressure can be 1.5 to 5.0 MPa, and the time can be 60 to 150 minutes.

The metal-clad laminate 11 may also be prepared by forming the film-like resin composition on the metal foil 13, and performing heating and pressurizing without using the prepreg 1.

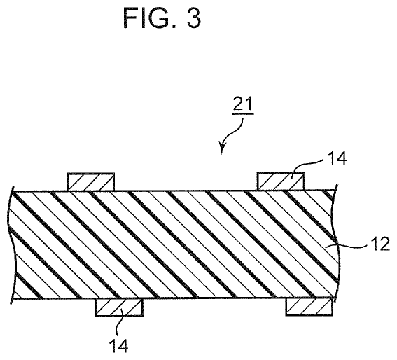

As shown in FIG. 3, the wiring board 21 of the present embodiment has the insulating layer 12 containing a cured product of the aforementioned resin composition or a cured product of the aforementioned prepreg, and the wiring 14.

It is preferred that the resin composition of the present embodiment is used as a material for an interlayer insulating layer of a wiring board. Although not particularly limited, it is preferred that the resin composition is used as a material for an interlayer insulating layer of a multilayer wiring board having 10 or more circuit layers, and further 15 or more circuit layers.

As the material for the interlayer insulating layer, it is preferred to use a plurality of insulating layers formed of the resin composition of the present embodiment. Although not particularly limited, for example, it is preferred to use 10 or more layers. This makes it possible to further densify the conductor circuit pattern in the multilayer wiring board, and would further improve the low dielectric characteristics in the plurality of interlayer insulating layers, insulation reliability between conductor circuit patterns, and insulation between interlayer circuits. Furthermore, the effect of increasing the transmission speed of signals in the multilayer wiring hoard, and reducing the loss during signal transmission is also obtained.

As a method for producing the wiring board 21, for example, by forming a circuit (wiring) by etching the metal foil 13 of the surface of the metal-clad laminate 13 obtained in the above, it is possible to obtain the wiring board 21 having a conductor pattern (wiring 14) provided as a circuit on the surface of the laminate. As a method for forming a circuit, circuit formation according to a semi additive process (SAP) or a modified semi additive process (MSAP) can be recited besides the method as described above.

Since the prepreg, the film with resin, and the metal foil with resin obtained by using the resin composition of the present embodiment combine excellent moldability, and low dielectric characteristics, low coefficient of thermal expansion, high Tg and adhesiveness and low water absorption in the cured products thereof, they are very useful in industrial applications. Also, the metal-clad laminate and the wiring board produced by curing these have high heat resistance, high Tg, high adhesiveness, low water absorption, and high conduction reliability.

While the present description discloses the techniques of various aspects as described above, the principal techniques thereof are summarized below.

A resin composition according to one aspect of the present invention includes a modified polyphenylene ether compound having a carbon-carbon unsaturated double bond at a molecular end, a maleimide compound having two or more N-substituted maleimide groups in one molecule, and a styrene-based polymer having a weight average molecular weight of less than 10000.

According to such a configuration, it would be possible to provide a resin composition combining excellent moldability in a prepreg, a film with resin, a metal foil with resin or the like containing the resin composition or a semi-cured product thereof, and low dielectric characteristics, high heat resistance, high Tg, low coefficient of thermal expansion, adhesiveness, and low water absorption in a cured product of the resin composition.

Further, in the resin composition, it is preferred that the modified polyphenylene ether compound has at least one of structures represented by formulas (1) and (2).

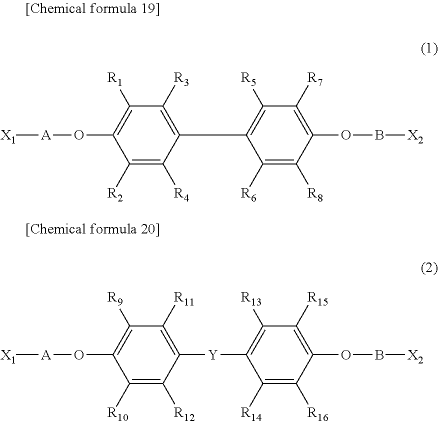

(In formulas (1) and (2), R₁ to R₈ and R₉ to R₁₆ each independently represent a hydrogen atom, an alkyl group, an alkenyl group, an alkynyl group, a formyl group, an alkylcarbonyl group, an alkenylcarbonyl group, or an alkynylcarbonyl group.)

In formulas (1) and (2), A and B respectively represent structures shown by formulas (3) and (4):

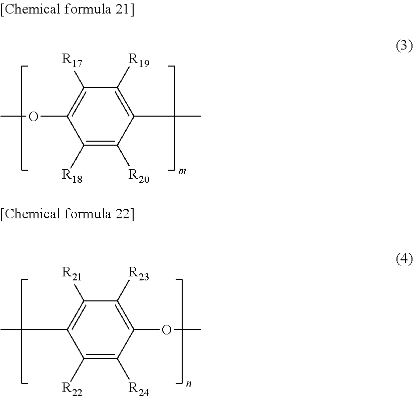

(In formulas (3) and (4), m and n each represent an integer of 1 to 50. R₁₇ to R₂₀ and R₂₁ to R₂₄ each independently represent a hydrogen atom or an alkyl group.)

Further, in formula (2), Y is a structure represented by formula (5):

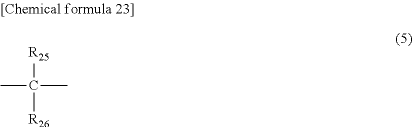

(In formula (5), R₂₅ and R₂₆ each independently represent a hydrogen atom or an alkyl group.)

X₁ and X₂ each independently represent a substituent having a carbon-carbon unsaturated double bond as represented by formula (6) or (7), and X₁ and X₂ may be the same or different.

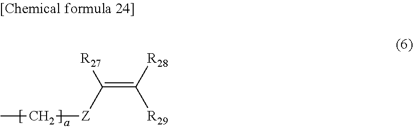

(In formula (6), a represents an integer of 0 to 10. Z represents an arylene group. R₂₇ to R₂₉ each independently represent a hydrogen atom or an alkyl group.)

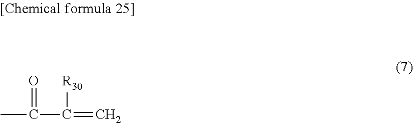

(In formula (7), R₃₀ represents a hydrogen atom or an alkyl group.)

This configuration would provide the aforementioned effect more reliably.

In the resin composition, it is preferred that the modified polyphenylene ether compound has a weight average molecular weight (Mw) of 1000 to 5000. This would provide more excellent moldability in addition to heat resistance.

Further, it is preferred that the modified polyphenylene ether compound has one to five functional groups in one molecule. This prevents the viscosity from increasing more reliably, and achieves high Tg and heat resistance more reliably.

In the resin composition, the content of the styrene-based polymer is preferably 5 to 50 parts by mass per 100 parts by mass of a total of the modified polyphenylene ether compound, the maleimide compound, and the styrene-based polymer. This would achieve high Tg, low CTE and low dielectric characteristics more reliably.

Further, it is preferred that the content ratio between the modified polyphenylene ether compound and the maleimide compound is 95:5 to 25:75. This results in the merits of showing high copper foil adhesiveness and high Tg, and having high heat resistance.

In the resin composition, it is preferred that the styrene-based polymer has a weight average molecular weight of 1000 to 7000. This would further improve the moldability and stability of the resin varnish.

Further, it is preferred that variation ΔDf[(Df−I)−(Df−II)] between dielectric loss tangent (Df−II) of the evaluation substrate at 10 GHz after dipping a cured product of the resin composition in water at 23° C. for 24 hours, and dielectric loss tangent (Df−I) before dipping is less than 0.0040. According to the present invention, it is possible to exert an excellent effect that low dielectric characteristics can be kept even in a high-humidity environment.

A prepreg according to another aspect of the present invention includes the aforementioned resin composition or a semi-cured product of the resin composition, and a fibrous base material.

A film with resin according to another aspect of the present invention includes a resin layer containing the aforementioned resin composition or a semi-cured product of the resin composition, and a support film.

A metal foil with resin according to another aspect of the present invention includes a resin layer containing the aforementioned resin composition or a semi-cured product of the resin composition, and a metal foil.

A metal-clad laminate according to another aspect of the present invention includes an insulating layer containing a cured product of the aforementioned resin composition or a cured product of the aforementioned prepreg, and a metal foil.

A wiring board according to another aspect of the present invention includes an insulating layer containing a cured product of the aforementioned resin composition or a cured product of the aforementioned prepreg, and wiring.

According to the above-described configuration, it is possible to obtain a prepreg, a film with resin, and a metal foil with resin having excellent moldability, and a prepreg, a film with resin, and a metal foil with resin, a metal foil with resin, a metal-clad laminate, a wiring board and so on capable of providing a substrate having low dielectric characteristics, high Tg and high heat resistance, low coefficient of thermal expansion (CTE), excellent adhesiveness and low water absorption, and high conduction reliability.

In the following, the present invention is described more specifically by examples, however, it is to be noted that the scope of the present invention is not limited to these examples.

### Examples

In the present example, components used in preparing a resin composition are described.

### Modified Polyphenylene Ether Compound

OPE-2St 1200: Terminally vinylbenzyl-modified PPE (Mw: about 1600, Mn 1200, available from MITSUBISHI GAS CHEMICAL COMPANY, INC.)
OPE-2St 2200: Terminally vinylbenzyl-modified PPE (Mw: about 3600, Mn 2200, available from MITSUBISHI GAS CHEMICAL COMPANY, INC.)
Modified PPE-1: Bifunctional vinylbenzyl-modified PPE (Mw: 1900)

First, a modified polyphenylene ether (modified PPE-1) was synthesized. An average number of phenolic hydroxyl groups at the molecular terminal per one molecule of polyphenylene ether is indicated by a number of terminal hydroxyl groups.

Polyphenylene ether and chloromethylstyrene were reacted to give modified polyphenylene ether 1 (modified PPE-1). Specifically, first, a 1-L three-necked flask equipped with a temperature controller, a stirrer, a cooler, and a dropping funnel was charged with 200 g of polyphenylene ether (SA90 available from SABIC Innovative Plastics, intrinsic viscosity (IV) 0.083 dl/g, number of terminal hydroxyl groups: 1.9, weight molecular weight Mw: 1700), 30 g of a mixture of p-chloromethylstyrene and m-chloromethylstyrene in a mass ratio of 50:50 (chloromethylstyrene available from TOKYO CHEMICAL INDUSTRY CO., LTD.: CMS), 1.227 g of tetra-n-butylammonium bromide as a phase transfer catalyst, and 400 g of toluene, and stirred. Then, the mixture was stirred until polyphenylene ether, chloromethylstyrene, and tetra-n-butylammonium bromide were dissolved in toluene. At this time, the mixture was gradually heated until the liquid temperature finally reached 75° C. Then, to the resultant solution, a sodium hydroxide aqueous solution (sodium hydroxide 20 g/water 20 g) as an alkali metal hydroxide was dropped over 20 minutes. Thereafter, the solution was further stirred at 75° C. for 4 hours. Then, after neutralizing the contents of the flask with 10% by mass of hydrochloric acid, a large amount of methanol was introduced. This made the liquid in the flask generate a precipitate. That is, the product contained in the reaction solution in the flask was reprecipitated. Then, the precipitate was taken out by filtration, and washed three times with a mixture of methanol and water in a mass ratio of 80:20, and dried at 80° C. for 3 hours under reduced pressure.

The obtained solid was analyzed by ¹H-NMR (400 MHz, CDCl3, TMS). In the measurement result of NMR, a peak originating from ethenylbenzyl was observed at 5 to 7 ppm. This demonstrated that the obtained solid was polyphenylene ether of which terminal was ethenylbenzylated.

The molecular weight distribution of the modified polyphenylene ether was determined by using GPC. From the obtained molecular weight distribution, a weight average molecular weight (Mw) was calculated. Mw was 1900.

Also, the number of terminal functional groups of the modified polyphenylene ether was determined in the following manner.

First, the modified polyphenylene ether was accurately weighed. The weight at this time is X (mg). Then, the weighed modified polyphenylene ether was dissolved in 25 mL of methylene chloride, and to the resultant solution, 100 μL of a 10% by mass solution of tetraethylammonium hydroxide (TEAR) in ethanol (TEAH:ethanol (volume ratio)=15:85) was added, and absorbance (Abs) at 318 nm was measured by using an UV spectrophotometer (UV-1600 available from Shimadzu Corporation). Then from the measurement result, the number of terminal hydroxyl groups of the modified polyphenylene ether was calculated using the following formula.

Residual OH quantity (μmol/g)=[(25×Abs)/(ε×OPL×X)]×106

In this specification, E represents an extinction coefficient, and is 4700 L/mol·cm. OPL represents a cell optical path length, and is 1 cm.

The calculated residual OH quantity (the number of terminal hydroxyl groups) of the modified polyphenylene ether was almost zero, revealing that almost all the hydroxyl groups of the polyphenylene ether before modification were modified. This revealed that the decrement from the number of terminal hydroxyl groups of the polyphenylene ether before modification was the number of terminal hydroxyl groups of the polyphenylene ether before modification. In other words, it was revealed that the number of terminal hydroxyl groups of the polyphenylene ether before modification was the number of terminal functional groups of the modified polyphenylene ether. That is, the number of terminal functional groups was 1.8. This is called “modified PPE-1”
SA-9000: Bifunctional methacrylate-modified PPE (Mw: 2000, available from SABIC)
SA90: Unmodified PPE, (Mw: 1700, available from SABIC Innovative Plastics)

### Maleimide Compound

MIR-3000: Maleimide compound represented by formula (10) (functional group equivalent of maleimide group 275 g/eq., available from Nippon Kayaku Co., Ltd.)
BMI-4000: Maleimide compound represented by formula (11) (functional group equivalent of maleimide group 285 g/eq., available from Daiwakasei Industry Co., Ltd.)
BMI-2300: Maleimide compound represented by formula (9) (functional group equivalent of maleimide group 180 g/eq., available from Daiwakasei Industry Co., Ltd.)
BMI-TMH: Maleimide compound represented by formula (12) (functional group equivalent of maleimide group 159 g/eq., available from Daiwakasei Industry Co., Ltd.)

### Styrene-Based Polymer

FTR6125: Styrene-aliphatic hydrocarbon-based copolymer (Mw 1950, available from Mitsui Chemicals, Inc.)
FTR2140: Styrene-(a-methylstyrene)-based copolymer (Mw 3230, available from Mitsui Chemicals, Inc.)
FTR0100: a-methylstyrene-based polymer (Mw 1960, available from Mitsui Chemicals, Inc.)
FMR0150: Styrene-aromatic hydrocarbon-based copolymer (Mw 2040, available from Mitsui Chemicals, Inc.)
FTR8120: Styrene-based polymer (Mw 1420, available from Mitsui Chemicals, Inc.)
SX-100: Styrene-based polymer (Mw 2000, available from YASUHARA CHEMICAL CO., LTD.)
S8007L: Hydrogenated SBS (styrene-butadiene-styrene) copolymer (Mw: about 100000, available from KURARAY CO., LTD.)

### Other Components

### Reaction Initiator

PERBUTYL P: 1,3-bis(butylperoxyisopropyl)benzene (available from NOF CORPORATION)

### Inorganic Filler

SC2500-SXJ: Phenylaminosilane surface treated spherical silica (available from Admatechs Company Limited)

### Examples 1 to 25, Comparative Example 1 to 9

### Preparation Method

### Resin Varnish

First, (A) modified PPE (or unmodified PPE), (B) maleimide compound, and (C) styrene-based polymer were added to methylethylketone (MEK) in a blending ratio described in Tables 1 to 3 so that the solid concentration of (A) to (C) was 40% by mass, and they were mixed and solved by stirring under heating at 70 ° C. for 60 minutes. The mixture was allowed to cool to 25 ° C., and then a peroxide, an inorganic filler and so on were added, and stirred and dispersed by a beads mill, to obtain a vamishy resin composition (MEK solution resin varnish). As to Comparative Examples 8 to 9, however, the inventors tried to prepare resin varnish by mixing the (A) component, the (B) component and the (C) component, but could not prepare MEK solution resin varnish because (C) component failed to dissolve.

As to Comparative Examples 8 to 9, resin varnish was prepared in the following method. The (A) component and the (B) component in the ratio described in Table 2 were added to MEK so that the solid concentration was 40% by mass, and they were mixed and solved by stirring under heating at 70° C. for 60 minutes. To the mixture, a predetermined amount of a toluene solution of the (C) component prepared to have a solid content of 20% by mass was added, and the mixture was allowed to cool to 25° C. under mixing and stirring, and then a peroxide, an inorganic filler and so on were added, and stirred and dispersed by a beads mill, to obtain a varnishy resin composition (MEK-toluene mixed solution resin varnish).

### Prepreg

Preparation of prepreg-I

After impregnating glass cloth (available from Asahi Kasei Corporation, #2116 type, E glass) with the resin varnish each of Examples and Comparative Examples prepared in the above, the prepreg was heat dried at 100 to 170° C. for about 3 to 6 minutes to give a prepreg. At that time, the content of the resin composition (resin content) relative to the weight of the prepreg was adjusted to about 48% by mass.
Preparation of Prepreg-II

After impregnating glass cloth (available from Asahi Kasei Corporation, #1067 type, E glass) with a resin varnish of each of Examples and Comparative Examples, the prepreg was heat dried at 100 to 170° C. for about 3 to 6 minutes to give a prepreg. At that time, the content of the resin composition (resin content) relative to the weight of the prepreg was adjusted to about 73% by mass.

### Copper-Clad Laminate

On both sides of one sheet of the prepreg-I, a copper foil having a thickness of 12 μm (GT-MP, available from FURUKAWA ELECTRIC CO., LTD.) was disposed to give an object to be compressed, and the object was heated and pressurized at a temperature of 220° C., with a pressure of 30 kgf/cm² in vacuo for 90 minutes to give a copper-clad laminate-I having a thickness of about 0.1 mm to which copper foils are adhered on both sides. Also, eight sheets of the prepreg were stacked, and a copper-clad laminate-II having a thickness of about 0.8 mm was obtained in the same manner as described above.

Also, twelve sheets of the prepreg-II were stacked, and a copper-clad laminate-III having a thickness of about 0.8 mm was obtained in the same manner as described above.

### Evaluation Tests

### Storage Stability of Resin Varnish

The MEK solution resin varnish (Examples 1 to 25 and Comparative Examples 1 to 7), and MEK-toluene mixed solution resin varnish (Comparative Examples 8 to 9) prepared above were left to stand at 25° C. for 24 hours, and when no change was observed in the varnish appearance, the varnish was evaluated as “good”, and when change in appearance such as precipitation of resin or separation of resin was observed, the varnish was evaluated as “poor”.

### Glass Transition Temperature (Tg)

The whole surface of the outer layer copper foil of the copper-clad laminate I was etched, and for the obtained sample, Tg was measured by using a viscoelasticity spectrometer “DMS100” available from Seiko Instruments Inc. At this time, dynamic viscoelasticity measurement (DMA) was performed by a tensile module at a frequency of 10 Hz, and the temperature at which tans showed the maximum when the temperature was elevated to 300° C. from the room temperature at a temperature elevation rate of 5° C./min was determined as Tg.

### Coefficient of Thermal Expansion (CTE-Z)

The copper foil was removed from the copper-clad laminate-Il to make a test piece, and for the test piece, the coefficient of thermal expansion in the Z-axial (compression) direction at a temperature less than the glass transition temperature of the resin cured product was measured by Thermo-mechanical analysis (TMA) method according to JIS C 6481. The measurement was performed in the range of 30 to 300° C. using a TMA apparatus (“TMA6000” available from SII Nano Technology). The measurement unit is ppm/° C.

### Copper Foil Adhesivity

In the copper-clad laminate I, copper foil peel strength of copper foil from the insulating layer was measured in accordance with JIS C 6481. A pattern of 10 mm wide and 100 mm long was formed, and tearing was performed at a rate of 50 mm/min with a tensile tester, and a tearing strength (peel strength) at this time was measured, and the peel strength was determined as a copper foil adhesion strength. The measurement unit was kN/m.

### Dielectric Characteristics: Dielectric Loss Tangent (Df)

Using a laminate obtained by removing the copper foil from the copper-clad laminate-III as a test piece, the test piece was dried in an oven at 105° C. for 2 hours to remove the moisture in the test piece. The test piece taken out of the oven was placed in a desiccator and allowed to cool to 25° C., and dielectric loss tangent (Df) of the test piece was measured by a cavity resonator perturbation method. Specifically, using a network analyzer (N5230A available from Agilent Technologies, Inc.), dielectric loss tangent (Df−I) of the test piece at 10 GHz was measured.

### Dielectric Characteristics: Df Variation After Water Absorption (ΔDf)

After dipping the dried test piece for dielectric loss tangent in water at 23° C. for 24 hours, the test piece from which the water on the surface was wiped off was measured for dielectric loss tangent (Df−II) of the evaluation substrate at 10 GHz in the same method as described above. ΔDf was determined according to the following calculation formula, and evaluation was made in the following criteria.

ΔDf=(Df−II)−(Df−I)

Excellent: Variation is less than 0.0025

Good: Variation is 0.0025 or more and less than 0.0030

Fair: Variation is 0.0030 or more and less than 0.0040

### Water Absorption

Using a laminate obtained by removing the copper foil from the copper-clad laminate-III as an evaluation substrate, water absorption was evaluated according to JIS-C6481 (1996). Water absorption condition is E-24/50+D-24/23 (namely, treatment in constant temperature air at 50° C. for 24 hours, and in constant temperature water at 23° C. for 24 hours). Water absorption was calculated according to the following formula:

Water absorption (%)=((mass after water absorption−mass before water absorption)/weight before absorption)×100

### Resin Fluidity

Resin fluidity was evaluated using the prepreg-II. Resin fluidity of the prepreg-II obtained by using resin varnish of Examples 1 to 9 was determined in accordance with IPC-TM-650. The prepreg was hot plate pressed for 15 minutes under the molding conditions of a temperature of 171° C. and a pressure of 14 kgf/cm². As to the number of prepregs for use in measurement, four prepregs-II prepared in the manner as described above were used.

### Circuit Fillability, Grid Pattern (Percentage of Remaining Copper) 50%

On both sides of one sheet of the prepreg-I, a copper foil having a thickness of 35 μm (GTHMP35, available from FURUKAWA ELECTRIC CO., LTD.) was disposed to give an object to be compressed, and the object was heated and pressurized at a temperature of 220° C., with a pressure of 30 kg/cm² for 90 minutes to give a copper-clad laminate having a thickness of 0.1 mm to which copper foils are adhered on both sides.

Then, for each of the copper foils on both sides of the copper-clad laminate, a grid-like pattern was formed so that the percentage of remaining copper was 50% to form a circuit. On each side of the substrate on which the circuit was formed, one sheet of prepreg-II was laminated, and a copper foil having a thickness of 12 μm (“GTHMP12” available from Furukawa Electric Co., Ltd.) was arranged to give an object to be compressed, and heating and pressurizing was conducted in the same conditions as those in production of the copper-clad laminate. Then, the outer layer copper foils were etched over the entire surface to obtain a sample. In the formed laminate (laminate for evaluation), if the resin composition derived from the prepreg sufficiently enter between the circuits, and voids were not formed, the sample was evaluated as “good”. If the resin composition derived from the prepreg failed to sufficiently enter between the circuits, and voids were formed, the sample was evaluated as “poor”. Voids can be visually confirmed.

These results are shown in Tables 1 to 3.

TABLE 1

| | | | Example 1 | Example 2 | Example 3 | Example 4 | Example 5 | Example 6 | Example 7 |
|---|---|---|---|---|---|---|---|---|---|
| Polyphenylene | OPE-2St 1200 | | 40 | 40 | | | | 40 | 40 |
| ether | OPE-2St 2200 | | | | 40 | | | | |
| compound | Modified PPE-1 | | | | | 40 | | | |
| | SA9000 | | | | | | 40 | | |
| | SA90 | | | | | | | | |
| Maleimide | MIR-3000 | | 30 | 30 | 30 | 30 | 30 | | |
| compound | BMI-4000 | | | | | | | 30 | |
| | BMI-2300 | | | | | | | | 30 |
| | BMI-TMH | | | | | | | | |
| Styrene- | FTR6125 | | 30 | 30 | 30 | 30 | 30 | 30 | 30 |
| based | FTR2140 | | | | | | | | |
| copolymer | FTR0100 | | | | | | | | |
| | FMR0150 | | | | | | | | |
| | FTR8120 | | | | | | | | |
| | SX-100 | | | | | | | | |
| | S8007L | | | | | | | | |
| Peroxide | PERBUTYL P | Peroxide | | 1 | 1 | 1 | 1 | 1 | 1 |
| Inorganic | SC2500-SXJ | Silica | 130 | 130 | 130 | 130 | 130 | 130 | 130 |
| filler | | | | | | | | | |
| Evaluation | Tg | ° C. | 200 | 210 | 200 | 190 | 190 | 210 | 210 |
| tests | | | | | | | | | |
| | CTE-Z | ppm/° C. | 38 | 35 | 35 | 35 | 35 | 35 | 35 |
| | Cu peel | kN/m | 0.5 | 0.5 | 0.5 | 0.5 | 0.5 | 0.5 | 0.5 |
| | Df@10 GHz | — | 0.0035 | 0.0040 | 0.0040 | 0.0040 | 0.0042 | 0.0040 | 0.0040 |
| | ΔDf | | Excellent | Excellent | Excellent | Excellent | Excellent | Excellent | Good |
| | Water | % | 0.15 | 0.20 | 0.20 | 0.20 | 0.20 | 0.20 | 0.25 |
| | absorption | | | | | | | | |
| | Resin fluidity | % | 20 | 20 | 15 | 15 | 15 | 20 | 20 |
| | of prepreg | | | | | | | | |
| | Circuit | — | Good | Good | Good | Good | Good | Good | Good |
| | fillability | | | | | | | | |
| | MEK solution | | Preparable | Preparable | Preparable | Preparable | Preparable | Preparable | Preparable |
| | resin varnish | | | | | | | | |
| | Storage | | Good | Good | Good | Good | Good | Good | Good |
| | stability of | | | | | | | | |
| | resin varnish | | | | | | | | |

| | | | Example 8 | Example 9 | Example 10 | Example 11 | Example 12 | Example 13 |
|---|---|---|---|---|---|---|---|---|
| Polyphenylene | OPE-2St 1200 | | 40 | 40 | 40 | 40 | 40 | 40 |
| ether | OPE-2St 2200 | | | | | | | |
| compound | Modified PPE-1 | | | | | | | |
| | SA9000 | | | | | | | |
| | SA90 | | | | | | | |
| Maleimide | MIR-3000 | | | 30 | 30 | 30 | 30 | 30 |
| compound | BMI-4000 | | | | | | | |
| | BMI-2300 | | | | | | | |
| | BMI-TMH | | 30 | | | | | |
| Styrene- | FTR6125 | | 30 | | | | | |
| based | FTR2140 | | | 30 | | | | |
| copolymer | FTR0100 | | | | 30 | | | |
| | FMR0150 | | | | | 30 | | |
| | FTR8120 | | | | | | 30 | |
| | SX-100 | | | | | | | 30 |
| | S8007L | | | | | | | |
| Peroxide | PERBUTYL P | Peroxide | 1 | 1 | 1 | 1 | 1 | 1 |
| Inorganic | SC2500-SXJ | Silica | 130 | 130 | 130 | 130 | 130 | 130 |
| filler | | | | | | | | |
| Evaluation | Tg | ° C. | 210 | 210 | 210 | 210 | 210 | 210 |
| tests | | | | | | | | |
| | CTE-Z | ppm/° C. | 35 | 35 | 35 | 35 | 35 | 35 |
| | Cu peel | kN/m | 0.5 | 0.55 | 0.5 | 0.5 | 0.5 | 0.5 |
| | Df@10 GHz | — | 0.0042 | 0.0040 | 0.0040 | 0.0040 | 0.0040 | 0.0040 |
| | ΔDf | | Good | Excellent | Excellent | Excellent | Excellent | Excellent |
| | Water | % | 0.25 | 0.20 | 0.20 | 0.20 | 0.20 | 0.20 |
| | absorption | | | | | | | |
| | Resin fluidity | % | 20 | 18 | 20 | 20 | 22 | 22 |
| | of prepreg | | | | | | | |
| | Circuit | — | Good | Good | Good | Good | Good | Good |
| | fillability | | | | | | | |
| | MEK solution | | Preparable | Preparable | Preparable | Preparable | Preparable | Preparable |
| | resin varnish | | | | | | | |
| | Storage | | Good | Good | Good | Good | Good | Good |
| | stability of | | | | | | | |
| | resin varnish | | | | | | | |

TABLE 2

| | | | Example 14 | Example 15 | Example 16 | Example 17 | Example 18 | Example 19 | Example 20 |
|---|---|---|---|---|---|---|---|---|---|
| Polyphenylene | OPE-2St 1200 | | 56 | 54 | 51 | 46 | 34 | 29 | 66.5 |
| ether | OPE-2St 2200 | | | | | | | | |
| compound | Modified PPE-1 | | | | | | | | |
| | SA9000 | | | | | | | | |
| | SA90 | | | | | | | | |
| Maleimide | MIR-3000 | | 42 | 41 | 39 | 34 | 26 | 21 | 3.5 |
| compound | BMI-4000 | | | | | | | | |
| | BMI-2300 | | | | | | | | |
| | BMI-TMH | | | | | | | | |
| Styrene- | FTR6125 | | 2.5 | 5 | 10 | 20 | 40 | 50 | 30 |
| based | FTR2140 | | | | | | | | |
| copolymer | FTR0100 | | | | | | | | |
| | FMR0150 | | | | | | | | |
| | FTR8120 | | | | | | | | |
| | SX-100 | | | | | | | | |
| | S8007L | | | | | | | | |
| Peroxide | PERBUTYL P | Peroxide | 1 | 1 | 1 | 1 | 1 | 1 | 1 |
| Inorganic | SC2500-SXJ | Silica | 130 | 130 | 130 | 130 | 130 | 130 | 130 |
| filler | | | | | | | | | |
| Evaluation | Tg | ° C. | 265 | 260 | 250 | 230 | 190 | 170 | 175 |
| tests | | | | | | | | | |
| | CTE-Z | ppm/° C. | 25 | 25 | 30 | 35 | 38 | 40 | 38 |
| | Cu peel | kN/m | 0.55 | 0.55 | 0.55 | 0.5 | 0.5 | 0.5 | 0.7 |
| | Df@10 GHz | — | 0.0047 | 0.0046 | 0.0045 | 0.0043 | 0.0035 | 0.0033 | 0.0035 |
| | ΔDf | | Fair | Fair | Good | Good | Excellent | Excellent | Excellent |
| | Water | % | 0.37 | 0.35 | 0.30 | 0.25 | 0.15 | 0.10 | 0.10 |
| | absorption | | | | | | | | |
| | Resin fluidity | % | 28 | 28 | 25 | 25 | 20 | 18 | 15 |
| | of prepreg | | | | | | | | |
| | Circuit | — | Good | Good | Good | Good | Good | Good | Good |
| | fillability | | | | | | | | |
| | MEK solution | | Preparable | Preparable | Preparable | Preparable | Preparable | Preparable | Preparable |
| | resin varnish | | | | | | | | |
| | Storage | | Good | Good | Good | Good | Good | Good | Good |
| | stability of | | | | | | | | |
| | resin varnish | | | | | | | | |

| | | | Example 21 | Example 22 | Example 23 | Example 24 | Example 25 |
|---|---|---|---|---|---|---|---|
| Polyphenylene | OPE-2St 1200 | | 63 | 56 | 35 | 21 | 17.5 |
| ether | OPE-2St 2200 | | | | | | |
| compound | Modified PPE-1 | | | | | | |
| | SA9000 | | | | | | |
| | SA90 | | | | | | |
| Maleimide | MIR-3000 | | 7 | 20 | 35 | 49 | 52.5 |
| compound | BMI-4000 | | | | | | |
| | BMI-2300 | | | | | | |
| | BMI-TMH | | | | | | |
| Styrene- | FTR6125 | | 30 | 30 | 30 | 30 | 30 |
| based | FTR2140 | | | | | | |
| copolymer | FTR0100 | | | | | | |
| | FMR0150 | | | | | | |
| | FTR8120 | | | | | | |
| | SX-100 | | | | | | |
| | S8007L | | | | | | |
| Peroxide | PERBUTYL P | Peroxide | 1 | 1 | 1 | 1 | 1 |
| Inorganic | SC2500-SXJ | Silica | 130 | 130 | 130 | 130 | 130 |
| filler | | | | | | | |
| Evaluation | Tg | ° C. | 180 | 200 | 210 | 220 | 230 |
| tests | | | | | | | |
| | CTE-Z | ppm/° C. | 35 | 35 | 35 | 30 | 30 |
| | Cu peel | kN/m | 0.7 | 0.6 | 0.5 | 0.45 | 0.4 |
| | Df@10 GHz | — | 0.0035 | 0.0038 | 0.0040 | 0.0042 | 0.0045 |
| | ΔDf | | Excellent | Excellent | Excellent | Good | Fair |
| | Water | % | 0.12 | 0.15 | 0.20 | 0.30 | 0.35 |
| | absorption | | | | | | |
| | Resin fluidity | % | 18 | 20 | 20 | 25 | 30 |
| | of prepreg | | | | | | |
| | Circuit | — | Good | Good | Good | Good | Good |
| | fillability | | | | | | |
| | MEK solution | | Preparable | Preparable | Preparable | Preparable | Preparable |
| | resin varnish | | | | | | |
| | Storage | | Good | Good | Good | Good | Good |
| | stability of | | | | | | |
| | resin varnish | | | | | | |

TABLE 3

| | | | Comparative | Comparative | Comparative | Comparative | Comparative |
|---|---|---|---|---|---|---|---|
| | | | Example 1 | Example 2 | Example 3 | Example 4 | Example 5 |
| Polyphenylene | OPE-2St 1200 | | 50 | 50 | 70 | 70 | |
| ether | OPE-2St 2200 | | | | | | |
| compound | Modified PPE-1 | | | | | | |
| | SA9000 | | | | | | |
| | SA90 | | | | | | |
| Maleimide | MIR-3000 | | 50 | 50 | | | 70 |
| compound | BMI-4000 | | | | | | |
| | BMI-2300 | | | | | | |
| | BMI-TMH | | | | | | |
| Styrene- | FTR6125 | | | | 30 | 30 | 30 |
| based | FTR2140 | | | | | | |
| copolymer | FTR0100 | | | | | | |
| | FMR0150 | | | | | | |
| | FTR8120 | | | | | | |
| | SX-100 | | | | | | |
| | S8007L | | | | | | |
| Peroxide | PERBUTYL P | Peroxide | | 1 | | 1 | |
| Inorganic | SC2500-SXJ | Silica | 130 | 130 | 130 | 130 | 130 |
| filler | | | | | | | |
| Evaluation | Tg | ° C. | 270 | 275 | 130 | 135 | 110 |
| tests | | | | | | | |
| | CTE-Z | ppm/° C. | 22 | 20 | 45 | 40 | 50 |
| | Cu peel | kN/m | 0.6 | 0.6 | 0.5 | 0.5 | 0.25 |
| | Df@10 GHz | — | 0.0050 | 0.0050 | 0.0030 | 0.0032 | 0.0040 |
| | ΔDf | | Poor | Poor | Excellent | Excellent | Fair |
| | Water | % | 0.50 | 0.55 | 0.05 | 0.08 | 0.35 |
| | absorption | | | | | | |
| | Resin fluidity | % | 30 | 30 | 15 | 15 | 40 |
| | of prepreg | | | | | | |
| | Circuit | — | Good | Good | Good | Good | Good |
| | fillability | | | | | | |
| | MEK solution | | Preparable | Preparable | Preparable | Preparable | Preparable |
| | resin varnish | | | | | | |
| | Storage | | Good | Good | Good | Good | Good |
| | stability of | | | | | | |
| | resin varnish | | | | | | |

| | | | Comparative | Comparative | Comparative | Comparative |
|---|---|---|---|---|---|---|
| | | | Example 6 | Example 7 | Example 8 | Example 9 |
| Polyphenylene | OPE-2St 1200 | | | | 40 | 40 |
| ether | OPE-2St 2200 | | | | | |
| compound | Modified PPE-1 | | | | | |
| | SA9000 | | | | | |
| | SA90 | | | 40 | | |
| Maleimide | MIR-3000 | | 70 | 30 | 30 | 30 |
| compound | BMI-4000 | | | | | |
| | BMI-2300 | | | | | |
| | BMI-TMH | | | | | |
| Styrene- | FTR6125 | | 30 | 30 | | |
| based | FTR2140 | | | | | |
| copolymer | FTR0100 | | | | | |
| | FMR0150 | | | | | |
| | FTR8120 | | | | | |
| | SX-100 | | | | | |
| | S8007L | | | | 30 | 30 |
| Peroxide | PERBUTYL P | Peroxide | 1 | | | 1 |
| Inorganic | SC2500-SXJ | Silica | 130 | 130 | 130 | 130 |
| filler | | | | | | |
| Evaluation | Tg | ° C. | 280 | 120 | 200 | 210 |
| tests | | | | | | |
| | CTE-Z | ppm/° C. | 30 | 50 | 38 | 35 |
| | Cu peel | kN/m | 0.3 | 0.3 | 0.7 | 0.7 |
| | Df@10 GHz | — | 0.0060 | 0.0055 | 0.0035 | 0.0040 |
| | ΔDf | | Poor | Fair | Excellent | Excellent |
| | Water | % | 0.60 | 0.35 | 0.15 | 0.20 |
| | absorption | | | | | |
| | Resin fluidity | % | 40 | 40 | 3 | 3 |
| | of prepreg | | | | | |
| | Circuit | — | Good | Good | Poor | Poor |
| | fillability | | | | | |
| | MEK solution | | Preparable | Preparable | Unpreparable | Unpreparable |
| | resin varnish | | | | | |
| | Storage | | Good | Good | Poor | Poor |
| | stability of | | | | | |
| | resin varnish | | | | | |

### Discussion

As is apparent from the results shown in Tables 1 to 3, it was revealed that the present invention can provide a resin composition having high Tg and excellent adhesiveness (peel 0.40 kN/m or more) in a cured product thereof, in addition to low dielectric characteristics (Df: 0.0045 or less). Also, it was confirmed that variation in Df was controlled even after water absorption by using the resin composition of the present invention. Further, in any example, the coefficient of thermal expansion (CTE) was as low as 40° C./ppm or less.

In particular, it was found that cured products that are more excellent in the above characteristics are obtained when the content of the styrene-based polymer and the content ratio of components fall within preferred ranges (Examples 15 to 25).

In contrast, sufficient dielectric characteristics and water absorption were not obtained, and variation in Df after water absorption was large in Comparative Example 1 in which a styrene-based polymer was not used. Even when a reaction initiator was added in Comparative Example 1, the same result was obtained (Comparative Example 2).

In Comparative Example 3 in which a maleimide compound was not used, sufficient Tg was not obtained, and CTE was large. Further, even when a reaction initiator was added in Comparative Example 3, Tg did not increase (Comparative Example 4).

Further, in Comparative Example 5 not containing a modified polyphenylene ether compound, curing of the resin composition (particularly, maleimide compound) did not proceed sufficiently, and Comparative Example 5 was inferior also in adhesiveness and ΔDf. When a reaction initiator was added in Comparative Example 5, the curing reaction proceeded, but Df and water absorption further deteriorated, and also ΔDf impaired (Comparative Example 6).

In Comparative Example 7, an unmodified polyphenylene ether compound was used, and also in this case, the curing reaction did not proceed sufficiently, and also Tg and adhesiveness were poor.

In Comparative Example 8 using a styrene-based polymer having a large molecular weight, the resin fluidity impaired, and sufficient circuit fillability was not obtained. Even when a reaction initiator was added in Comparative Example 8, the same was obtained (Comparative Example 9). The styrene-based polymer having a large molecular weight is soluble only in toluene. Further, the resin varnish prepared by using a MEK-toluene mixed solution showed the results lacking the varnish storage stability as evidenced by precipitation of the maleimide compound having high polarity due to the presence of toluene and the styrene-based polymer having high hydrophobicity and a large molecular weight, and resin separation due to deterioration in solubility of the styrene-based polymer (Comparative Examples 8, 9).

The present application is based on Japanese Patent Application No. 2019-67682 filed on Mar. 29, 2019, and the content thereof is incorporated in the present application.

While the present invention has been described appropriately and sufficiently in the above through the embodiments by referring to specific examples, drawings and so on for expressing the present invention, it is to be recognized that a person skilled in the art can easily change and/or modify the aforementioned embodiments. Therefore, it is interpreted that a changed form or a modified form made by a person skilled in the art is encompassed in the scope of a claim unless the changed form or the modified form departs from the scope of the claim disclosed in the claim.

### INDUSTRIAL APPLICABILITY

The present invention has broad industrial applicability in technical fields concerning electronic materials and electronic devices.

1. A resin composition comprising:
a modified polyphenylene ether compound having a carbon-carbon unsaturated double bond at a molecular end;
a maleimide compound having two or more N-substituted maleimide groups in one molecule; and
a styrene-based polymer having a weight average molecular weight of less than 10000.

2. The resin composition according to claim 1, wherein the modified polyphenylene ether compound has at least one of structures represented by formulas (1) and (2): 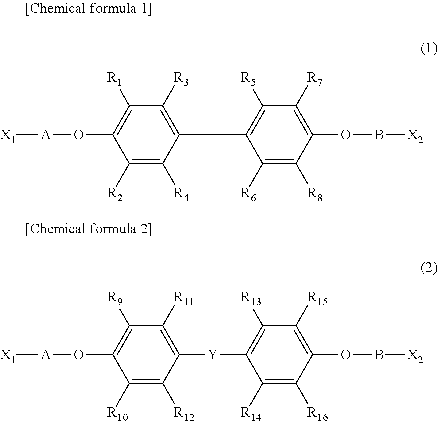
wherein R₁ to R₈ and R₉ to R₁₆ each independently represent a hydrogen atom, an alkyl group, an alkenyl group, an alkynyl group, a formyl group, an alkylcarbonyl group, an alkenylcarbonyl group, or an alky nylcarbonyl group, and
A and B respectively represent structures shown by formulas (3) and (4): 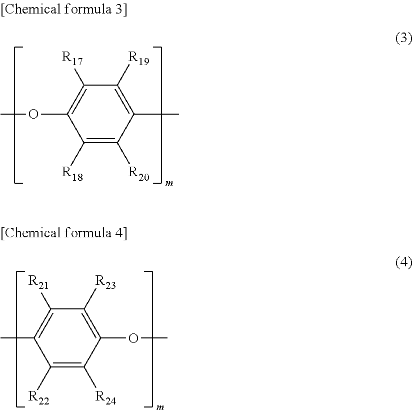
wherein m and n each represent an integer of 1 to 50, and R₁₇ to R₂₀ and R₂₁ to R₂₄ each independently represent a hydrogen atom or an alkyl group, and in formula (2), Y is a structure represented by formula (5): 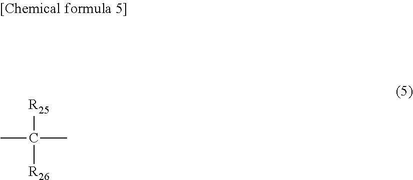
wherein R₂₅ and R₂₆ each independently represent a hydrogen atom or an alkyl group, and
X₁ and X2 each independently represent a substituent having a carbon-carbon unsaturated double bond as represented by formula (6) or (7), and Xi and X2 may be the same or different, 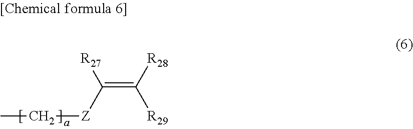
wherein a represents an integer of 0 to 10, Z represents an arylene group, and R₂₇ to R₂₉ each independently represent a hydrogen atom or an alkyl group, 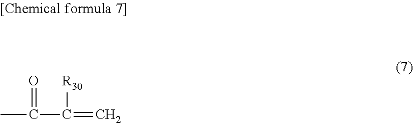
wherein R₃₀ represents a hydrogen atom or an alkyl group.

3. The resin composition according to claim 1, wherein the modified polyphenylene ether compound has a weight average molecular weight (Mw) of 1000 to 5000.

4. The resin composition according to claim 1, wherein the modified polyphenylene ether compound has one to five functional groups in one molecule.

5. The resin composition according to claim 1, wherein a content of the styrene-based polymer is 2.5 to 50 parts by mass per 100 parts by mass of a total of the modified polyphenylene ether compound, the maleimide compound, and the styrene-based polymer.

6. The resin composition according to claim 1, wherein a content ratio between the modified polyphenylene ether compound and the maleimide compound is 95:5 to 25:75.

7. The resin composition according to claim 1, wherein the styrene-based polymer has a weight average molecular weight of 1000 to 7000.

8. The resin composition according to claim 1, wherein variation ΔDf[(Df−II)−(Df−I) between dielectric loss tangent (Df−II) of an evaluation substrate at 10 GHz after dipping a cured product of the resin composition in water at 23° C. for 24 hours, and dielectric loss tangent (Df−I) before dipping is less than 0.0040.

9. A prepreg comprising:
the resin composition according to claim 1, or a semi-cured product of the resin composition; and
a fibrous base material.

10. A film with resin, comprising:
a resin layer containing the resin composition according to claim 1, or a semi-cured product of the resin composition; and
a support film.

11. A metal foil with resin, comprising:
a resin layer containing the resin composition according to claim 1, or a semi-cured product of the resin composition; and
a metal foil.

12. A metal-clad laminate, comprising:
an insulating layer containing a cured product of the resin composition according to claim 1; and
a metal foil.

13. A wiring board, comprising:
an insulating layer containing a cured product of the resin composition according to claim 1; and
wiring.

14. A metal-clad laminate, comprising:
an insulating layer containing a cured product of the prepreg according to claim 9 and a metal foil.

15. A wiring board, comprising:
an insulating layer containing a cured product of the resin composition according to a cured product of the prepreg according to claim 9 and wiring.
